(19) United States
(12) Patent Application Publication
(10) Pub. No.: US 2004/0019841 A1
(43) Pub. Date: Jan. 29, 2004

(54) Internally generating patterns for testing in an integrated circuit device

(76) Inventor: Adrian E. Ong, Pleasanton, CA (US)

Correspondence Address: Philip W. Woo, SIDLEY AUSTIN BROWN & WOOD LLP, 555 Califronia St., Suite 5000, San Francisco, CA, 94104-1715, US

(21) Appl. No.: 10/205,883

(22) Filed: Jul. 25, 2002

(51) Int. Cl. G11C 29/00; G06F 11/00; G01R 31/28

(52) U.S. Cl. 714/738

(57) ABSTRACT

A system is provided for testing an array of addressable locations implemented on an integrated circuit device, wherein each location identified by a respective address represented by a respective N-bit number. The system is operable to receive data for setting an initial address and for designating a least significant bit for the N-bit numbers. The system is further operable to generate a sequence of addresses beginning with the initial address and derived by incrementing or decrementing the least significant bit.

### FIELD OF THE INVENTION

The current invention relates to the integrated circuits (IC) devices, and in particular, internally generating patterns for testing in an integrated circuit device.

### BACKGROUND OF THE INVENTION

In the field of integrated circuit (IC) devices, several semiconductor die (commonly referred to as “chips”) can be combined into a single protective package. In some applications, such as that disclosed in U.S. patent application Ser. No. 09/666,208 filed on Dec. 21, 2000, entitled “Chip Testing Within a Multi-Chip Semiconductor Package,” which is assigned to the same assignee and incorporated by reference herein, a memory chip can be combined with a larger chip to provide both the functions of processing and storage of data. In such a combination, the number of external pins available for interacting with the logic or memory chips may be less than that which would be used if the two chips were packaged separately. Accordingly, there is a reduction in the overall number of external pins available for access to and from the chips.

It is important that packaged semiconductor devices be tested for quality before such devices are made available or sold to a customer. In the situation of multiple chips incorporated into a single package, testing can be made more complex if there is a reduction in the overall number of external pins. This is because many signals conveying patterns and addresses for use in testing are typically applied through external pins.

### SUMMARY OF THE INVENTION

The present invention provides, in various embodiments, system and methods for internally generating test data and addresses within an integrated circuit device for testing of the same. Internal generation of such patterns is beneficial, especially in the context of multiple chips placed into a single package with reduction in external pin count.

In accordance with an embodiment of the present invention, a system is provided for internally generating addresses for testing in an integrated circuit device having an array of addressable locations, said addresses being defined by N address bits. The system includes a first latching component for receiving and latching a value for an initial address, and a second latching component for receiving and latching data for designating one of the N address bits as a least significant bit for counting. A test address counter may be coupled to the first latching component and the second latching component. The test address counter is operable to generate a sequence of addresses for accessing a plurality of addressable locations in the array, wherein the sequence of addresses is represented by respective values which are derived by incrementing or decrementing the one of the N address bits designated as the least significant bit from the value for the initial address. The first address of the sequence can be the initial address. The first latching component, the second latching component, and the test address counter are implemented on the integrated circuit device.

In accordance with another embodiment of the present invention, a system is provided for testing an array of addressable locations implemented on an integrated circuit device, wherein each location identified by a respective address represented by a respective N-bit number. The system is operable to receive data for setting an initial address and for designating a least significant bit for the N-bit numbers. The system is further operable to generate a sequence of addresses beginning with the initial address and derived by incrementing or decrementing the least significant bit.

Important technical advantages of the present invention are readily apparent to one skilled in the art from the following figures, descriptions, and claims.

### DESCRIPTION OF THE DRAWINGS

For more complete understanding of the present invention and for further features and advantages, reference is now made to the following description taken in conjunction with accompanying drawings, in which:

FIG. 1 illustrates a system for internally generating patterns for testing within an integrated circuit device, according of an embodiment of the present invention.

FIG. 2 is a block diagram of a test row address sequencer, according to an embodiment of the present invention.

FIG. 3 is a block diagram of a test column address sequencer, according to an embodiment of the present invention.

FIG. 4 is a schematic diagram for a row test address counter, according to an embodiment of the present invention.

FIG. 5 is a schematic diagram for a column test address counter, according to an embodiment of the present invention.

FIG. 6 is a schematic diagram for a test counter section, according to an embodiment of the present invention.

FIG. 7 is a schematic diagram of one implementation for a flip-flop.

FIG. 8 is a schematic diagram of a set address latch, according to an embodiment of the present invention.

FIG. 9 is a schematic diagram of a set least significant bit latch, according to an embodiment of the present invention.

FIG. 10 is a schematic diagram of one implementation for a pass gate.

### DETAILED DESCRIPTION OF THE PREFERRED EMBODIMENTS

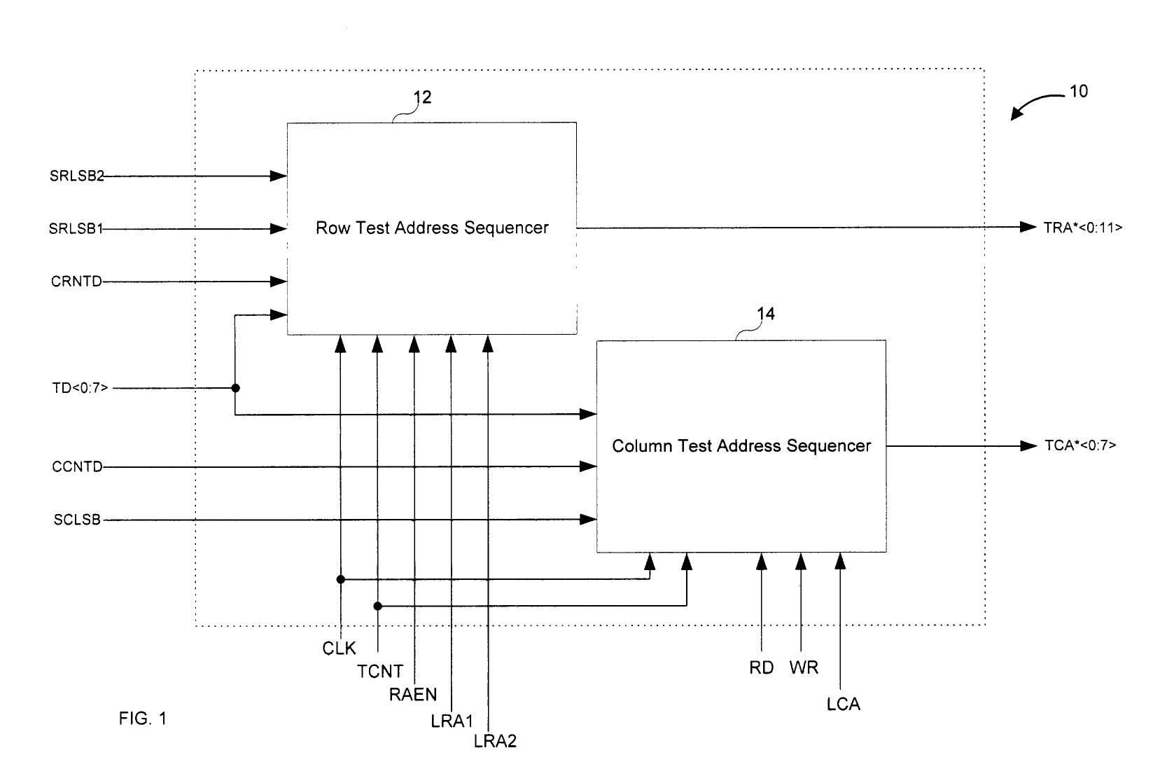

The preferred embodiments of the present invention and their advantages are best understood by referring to FIGS. 1 through 10 of the drawings. Like numerals are used for like and corresponding parts of the various drawings.

System for Internally Generating Patterns for Testing

FIG. 1 illustrates a system 10 for internally generating patterns for testing within an integrated circuit device, according of an embodiment of the present invention. System 10 may be implemented and incorporated on an integrated circuit “chip,” which can be a monolithic semiconductor structure or die formed from, for example, silicon or other suitable material.

Such chip can be a dynamic random access memory (DRAM), synchronous DRAM (SDRAM), static RAM (SRAM), non-volatile RAM (NVRAM), programmable read only memory (PROM), erasable programmable ROM (EPROM), electrically erasable programmable ROM (EEPROM), flash memory, or any other suitable memory chip. The chip could also be field programmable gate array (FPGA), programmable logic device (PLD), application specific integrated circuit (ASIC), a microprocessor, a microcontroller, or a digital signal processor (DSP), or other suitable logic chip.

The chip on which system 10 is incorporated can be packaged by itself or it can be one chip in a package containing multiple chips. It should also be understood that the systems, apparatuses, and methods of the present invention are not limited by the type of chip packaging and is applicable for any type of chip or multi-chip semiconductor packaging. As an example, the chip can be packaged as a standard ball grid array (BGA), micro-ball grid array (MBGA), or thin quad flatpack (TQFP) having suitable leads or other connecting points extending therefrom. However, other types of packaging may be used. For example, the chip packaging may have a ceramic base with chips wire bonded or employing thin film substrates, mounted on a silicon substrate, or mounted on a printed circuit board (PCB) or multi-chip module (MCM) substrate such as a multi-chip package (MCP). The packaging may further utilize various surface mount technologies such as a single in-line package (SIP), dual in-line package (DIP), zig-zag in-line package (ZIP), plastic leaded chip carrier (PLCC), small outline package (SOP), thin SOP (TSOP), flatpack, and quad flatpack (QFP), to name but a few, and utilizing various leads (e.g., J-lead, gull-wing lead) or BGA type connectors.

Integrated circuit memory implemented in memory chips (or embedded in logic chips) is typically made up of a number of memory locations or cells. These cells are physically arranged in rows and columns. Each memory cell has a respective “column address” and “row address” which uniquely identifies its location. The row and column addresses can be numerical values. For example, a row address can be a 12-bit binary number, and a column address can be an 8-bit binary number. Row and column addresses are provided to peripheral circuitry located on memory chips in order to access the memory cells for input and retrieval (writing/reading) of data or information.

System 10 generally functions to generate patterns to be used in testing of the integrated circuit device on which it is incorporated. These patterns can be sequences of data or addresses to be used during testing. For clarity, the remainder of this description primarily discusses embodiments of system 10 (and related methods and apparatuses) wherein the sequences are used as addresses, but it should be understood that the invention is not so limited. Such address sequences may comprise one or more addresses for various cells in one or more memory arrays, such as may be found in a memory chip or logic chip with embedded memory. The address sequences may be provided to peripheral circuitry for access to the appropriate memory cells. System 10 is advantageous because the row and column addresses for memory cells are internally generated with the chip, and thus no external pins are required for supporting the provision of addresses to the chip during testing.

As depicted, system 10 may include a row test address sequencer 12 and a column test address sequencer 14. These test address sequencers 12 and 14 may function to generate sequences of addresses for rows and columns, respectively. In some embodiments, these sequences of addresses can be essentially incrementing or decrementing values from an initial value. That is, each of test address sequencers 12 and 14 may “count up” or “count down” from some respective initial values, for example, in increments or decrements of 1, 2, 4, 8, etc.

Row test address sequencer 12 receives test data (TD[0:7]) signal, set row least significant bit 1 (SLRSB1) signal, set row least significant bit 2 (SRLSB2) signal, and a count row down (CRNTD) signal. The TD[0:7] signal may convey information or data for an initial value (or row address). The CRNTD signal may convey information or data for causing the row test address sequencer to count up or count down from the initial value. The TD[0:7] signal and the SRLSB1, SRLSB2 signals may convey information or data for defining a least significant bit (LSB) in the initial value. The size of increments or decrements (e.g., 1, 2, 4, etc.) as row test address sequencer 12 counts depends on which bit in the initial value is defined as the LSB. Row test address sequencer 12 also receives, a start counter (TCNT) signal, a row address enable (RAEN) signal, a first load row address (LRA1) signal, and a second load row address (LRA2) signal. In one embodiment, row test address sequencer 12 may receive a clock (CLK) signal for synchronous designs; in other embodiments, no clock signal is needed for asynchronous designs. Row test address sequencer 12 outputs a test row address (TRA[0:11]) signal which may be applied to a row address buffer for a memory array. The TRA[0:11] signal may convey a sequence of values (corresponding to row addresses) which can be used to access memory cells at particular rows in the memory array.

Column test address counter 14 receives the test data TD[0:7] signal, a count column down (CCNTD) signal, and a set column least significant bit (SCLSB) signal. The TD[0:7] signal may convey information or data for an initial value (or column address). The CCNTD signal may convey information or data for causing the column test address sequencer to count up or count down from the initial value. The TD[0:7] signal and the SCLSB signals may convey information or data for defining a least significant bit (LSB) in the initial value. The size of increments or decrements (e.g., 1, 2, 4, etc.) as column test address sequencer 14 counts depends on which bit in the initial value is defined as the LSB. Column test address counter 14 also received the CLK signal, the TCNT signal, a read (RD) signal, a write (WR) signal, a load column address (LCA) signal. Column test address counter 14 may output a test column address (TCA[0:7]) signal which may be applied to a column address buffer for a memory array. The TCA[0:7] signal may convey a sequence of values (corresponding to column addresses) which can be used to access memory cells at particular columns in the memory array.

A portion (up to all) of the input signals for row test address sequencer 12 and column test address sequencer 14 may be provided from circuitry on the same or a separate integrated circuit chip. For example, in one embodiment, the TD[0:7] signal may be provided from a data output circuit or an external testing output circuit, such as described in related U.S. application Ser. No. 09/967389 filed on Sep. 28, 2001, entitled “Testing Of Integrated Circuit Devices” and incorporated herein by reference in its entirety.

TRA[0:11] and TCA[0:7] signals can each convey sequences of addresses for testing of the memory. With these signals, the cells of a memory array in the integrated circuit chip can be addressed according to incrementing/decrementing rows and columns starting from any particular row/column address and in a variety of steps (1, 2, 4, 8, etc.). As such, system 10 provides significant flexibility in testing of the integrated circuit memory.

In operation, for each of row test address sequencer 12 and column test address sequencer 14, information for a respective starting or initial number (which can be for a row address or column address) is loaded via the TD[0:7] signal. This initial number for row test address sequencer 12 can be for an initial row address. The initial number for column test address sequencer 14 can be for an initial column address. Information for a least significant bit (LSB) for each initial number is provided by TD[0:7] signal and the SRLSB1, SRLSB2, and SCLSB signals. The setting of the LSB controls the size of increments/decrements as counting proceeds from the initial numbers. The CRNTD and the CCNTD signals are applied to the test address sequencers 12 and 14 to make the respective sequencer “count up” or “count down” from the initial number. In one embodiment, if the respective count down signal has a high (“logic 1”) value, then the test address sequencer counts up; and if the count down signal has a low (“logic 0”) value, then the test address sequencer counts down.

For any initial number and setting for LSB, the same group of addresses will be generated. As between different initial numbers and settings for LSB, only the order or sequence of addresses will differ when row test address sequencer 12 or column test address sequencer 14 is counting.

Thus, for example, assume for simplicity that there are only eight addresses which are defined by some combination of three address bits (A0, A1, A2). If the initial address is selected to be defined by A0=0, and A2=0, A0 is selected to be the LSB, and direction of counting is set to count up, then the resultant sequence is as follows:

| A2 | A1 | A0 |
|---|---|---|
| 0 | 0 | 0 |
| 0 | 0 | 1 |
| 0 | 1 | 0 |
| 0 | 1 | 1 |
| 1 | 0 | 0 |
| 1 | 0 | 1 |
| 1 | 1 | 0 |
| 1 | 1 | 1 |

As another example, if the initial address is selected to be defined by A0=0, A1=1, and A2=1, A1 is selected to be LSB, and direction of counting is set to count down, then the resultant sequence is as follows:

| A2 | A1 | A0 |
|---|---|---|
| 1 | 1 | 0 |
| 1 | 0 | 0 |
| 0 | 1 | 0 |
| 0 | 0 | 0 |
| 1 | 1 | 1 |
| 1 | 0 | 1 |
| 0 | 1 | 1 |
| 0 | 0 | 1 |

As yet another example, if the initial address is selected to be defined by A0=1, A1=1, and A2=0, A2 is selected to be the LSB, and direction of counting is set to count up, then the resultant sequence is as follows:

| A2 | A1 | A0 |
|---|---|---|
| 0 | 1 | 1 |
| 1 | 1 | 1 |
| 0 | 0 | 0 |
| 1 | 0 | 0 |
| 0 | 0 | 1 |
| 1 | 0 | 1 |
| 0 | 1 | 0 |
| 1 | 1 | 0 |

Row Test Address Sequencer

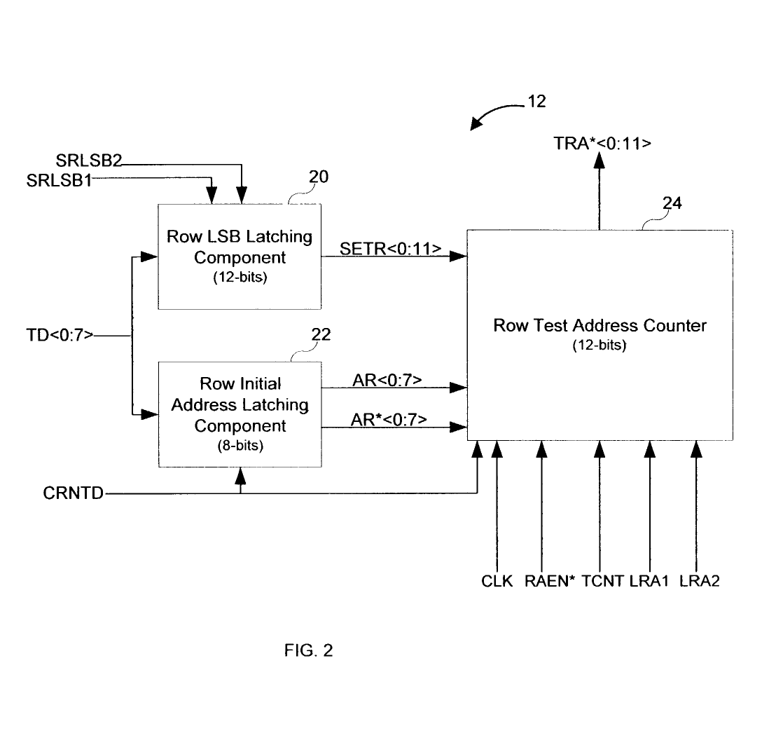

FIG. 2 is a block diagram of a test row address sequencer 12, according to an embodiment of the present invention. As depicted, test row address sequencer 12 includes a row address least significant bit (LSB) latching component 20, a row initial address latching component 22, and a row test address counter 24.

Row initial address latching component 22 generally function to latch values of the TD[0:7] signal, which are used to define a starting or initial number (or row address) from which counting may proceed. In one embodiment, this initial number can be a 12-bit binary number (address). Row initial address latching component 22, which may comprise one or more latching elements, receives the CRNTD signal and outputs address (AR[0:7] and AR*[0:7]) signals. These address signals specify the address for an initial row from which counting begins.

Row LSB latching component 20 generally function to latch values of the TD[0:7] signal, which are used to define a least significant bit for counting. The SRLSB2 and SRLSB1 signals are used to set the LSB for row address counting. Row LSB latching component 20 outputs a set (SETR[0:11]) signal. The SETR[0:11] signal serves to determine which bit in a row test address counter 24 will be used as the least significant bit (LSB) during the count.

The Row LSB latching component 20 and row initial address latching component 22 may be separately loaded using the same set of buffers.

Row test address counter 24 is connected to latching components 20 and 22. As used herein, the terms “couple,” “connected,” or any variant thereof means any coupling or connection, either direct or indirect, between two or more elements. Row test address counter 24 uses the SETR[0:11] and the AR[0:7], AR*[0:7] signals from latches 20 and 22 to generate the TRA[0:11] signals, which is then provided to address buffers. Row test address counter 24 generally functions to “count” a series of row addresses for testing.

Column Test Address Sequencer

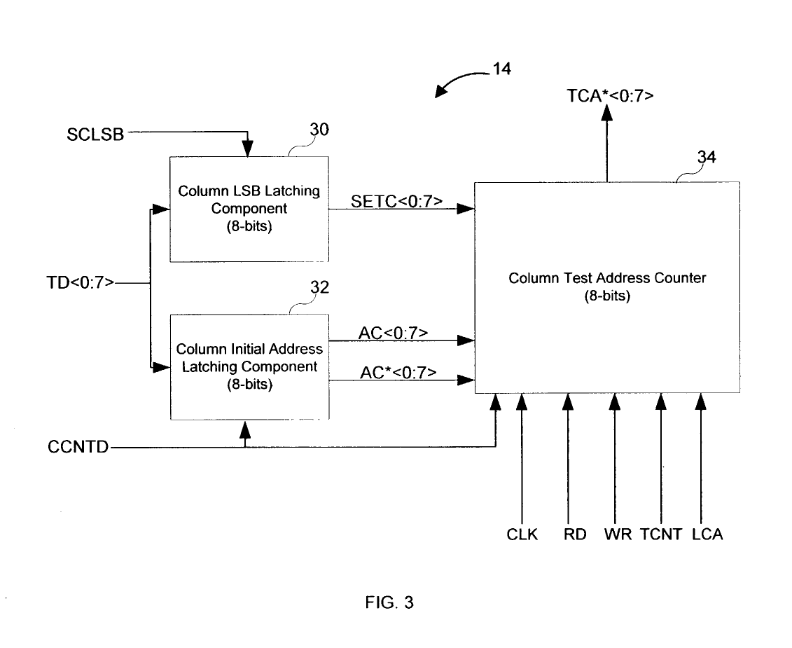

FIG. 3 is a block diagram of a test column address sequencer 14, according to an embodiment of the present invention. As depicted, test row address sequencer 12 includes a column least significant bit (LSB) latching component 30, a column initial address latching component 32, and a column test address counter 34.

Column initial address latching component 32 generally function to latch values of the TD[0:7] signal, which are used to define a starting or initial number (or column address) from which counting may proceed. In one embodiment, this initial number can be an 8-bit binary number (address). Column initial address latching component 32, which may comprise one or more latching elements, receives the CCNTD signal and outputs address (AC[0:7] and AC*[0:7]) signals. These address signals specify the address for an initial column from which counting begins.

Column LSB latching component 30 generally function to latch values of the TD[0:7] signal, which are used to define a least significant bit for counting. The SCLSB signal is used to set the LSB for column address counting. Column LSB latching component 20 outputs a set (SETC[0:7]) signal. The SETC[0:7] signal serves to determine which bit in the column test address counter 34 will be used as the least significant bit (LSB) during the count.

Column test address counter 34 is connected to latching components 30 and 32. Column test address counter 34 uses the SETC[0:11] and the AC[0:7], AC*[0:7] signals from latching components 30 and 32 to generate the TCA [0:7] signal, which is then provided to address buffers. Column test address counter 34 generally functions to “count” a series of columns addresses for testing.

The column LSB latching component 30 and column initial address latching component 32 may be separately loaded using the same set of buffers.

Row Test Address Counter

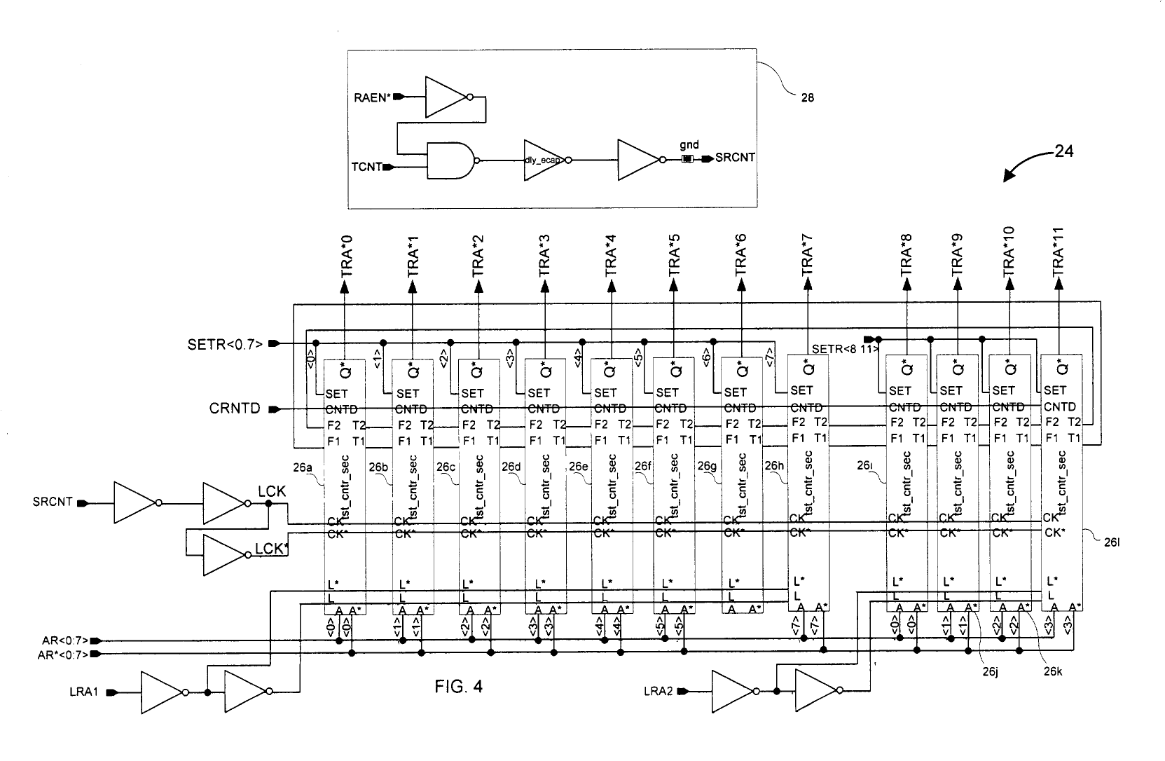

FIG. 4 is a schematic diagram for a row test address counter 24, according to an embodiment of the present invention. It should be understood that the implementation depicted in FIG. 4 is merely exemplary and that other implementations are contemplated, would be understood by those of ordinary skill, and are within the scope of present invention.

Row test address counter 24 may include a number of test counter sections (tst_cntr_sec) 26, which are separately labeled 26a-l. Test counter sections 26 may be coupled serially or in cascode in order to implement a counter. That is, one or more output signals (T1, T2) of one test counter section 26 are applied as input signals (F1l, F2) to the next section 26. A first group of test counter sections 26a-h are connected to receive a respective one of the row address bit signals (AR[0:7] and/or AR*[0:7]), in response to the application of the LRA1 signal. A second group of test counter sections 26i-l are connected to receive a respective one of the row address bit signals (AR[0:7] and/or AR*[0:7]), in response to the application of the LRA2 signal. In other words, the LRA1 and LRA2 signals are applied to test counter sections 26a-l in order to load the initial address from row initial address latching component 22.

In one embodiment, two cycles (e.g., of a CLK signal) may be required to set up row test address sequencer 12. In a first cycle, the first group of test counter sections 26a-h are loaded with respective values for an initial row address and a least significant bit; and in a second cycle, the second group of test counter sections 26i-l are loaded with respective values for the initial row address and the least significant bit.

Each test counter section 26a-l receives the CRNTD signal and a respective one of the SETR[0:11] signals. The SETR[0:11] signals generally function to specify one of the bits stored in one of test counter sections 26 as the least significant bit (LSB) so that counting proceeds in increments of 1, 2, 4, 8, etc. Test counter section 26a-l collectively output a sequence numbers, which can be row addresses conveyed in the output TRA[0:11] signals (appearing at the Q* output terminals of the test counter sections). The TRA[0:11] signals may be conveyed to the periphery circuitry of a memory array for access of particular rows during testing.

In the depicted embodiment, row test address counter 24 may be a synchronous counter, which is timed with a suitable clock signal. In particular, the signals at Q/Q* output terminals switch at substantially the same time when a LCK or LCK* signal goes, for example, active high. A shift register count generator 28, which receives the RAEN and TCNT signals, generates a start row count (SRCNT) signal. The SRCNT signal is used to generate the LCK and a LCK* signals. The LCK and LCK* signals are applied to clock inputs of the test counter sections 26a-l, thus causing the test address counter 24 to output a sequence of row addresses conveyed in the TRA[0:11] signals.

Column Test Address Counter

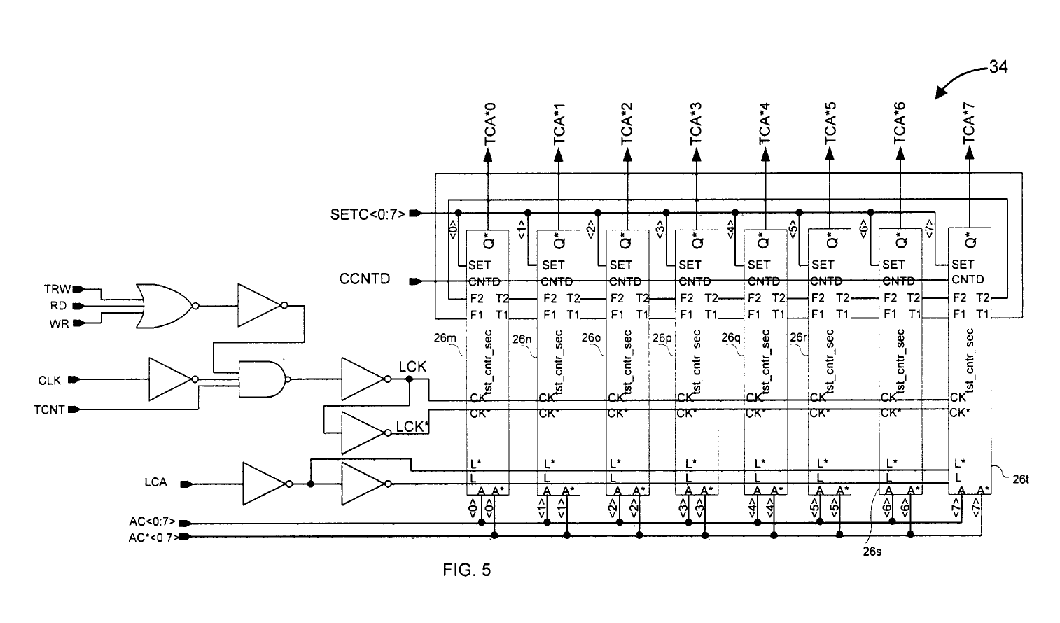

FIG. 5 is a schematic diagram for a column test address counter 34, according to an embodiment of the present invention. It should be understood that the implementation depicted in FIG. 5 is merely exemplary and that other implementations are contemplated, would be understood by those of ordinary skill, and are within the scope of present invention.

Column test address counter 34 may include a number of test counter sections (tst_cntr_sec) 26, which are separately labeled 26m-s. Test counter sections 26m-s may be coupled serially or in cascode in order to implement a counter. More specifically, one or more output signals (T1, T2) of one test counter section 26 are applied as input signals (F1, F2) to the next section 26. Test counter sections 26m-s are connected to receive a respective one of the column address signals (AC[0:7] and/or AC*[0:7]), in response to the application of the LCA signal.

Each test counter section 26m-s receives the CCNTD signal and a respective one of the SETC[0:7] signals. The SETC[0:7] signals generally function to specify one of the bits stored in one of test counter sections 26 as the least significant bit (LSB) so that counting proceeds in increments of 1, 2, 4, 8, etc. Test counter sections 26m-s collectively output a sequence numbers, which can be column addresses conveyed in the output TCA[0:7] signals (appearing at Q* output terminals of the test counter sections). The TCA[0:7] signals may be conveyed to the periphery circuitry of a memory array for access of particular columns during testing. In one embodiment, test counter sections 26m-s may be loaded with respective values for an initial column address and a least significant bit (which, for a synchronous design, can be accomplished in a single clock cycle).

In the depicted embodiment, column test address counter 34 may be a synchronous counter, which is timed with a suitable clock signal. In particular, the signals at Q/Q* output terminals switch at substantially the same time when a LCK or LCK* signal goes, for example, active high. The TCNT signal is used to generate the LCK and a LCK* signals. The LCK and LCK* signals are applied to clock inputs of the test counter sections 26m-s, thereby causing the test address counter 34 to output a sequence of column addresses conveyed in the TCA[0:7] signals.

Test Counter Section

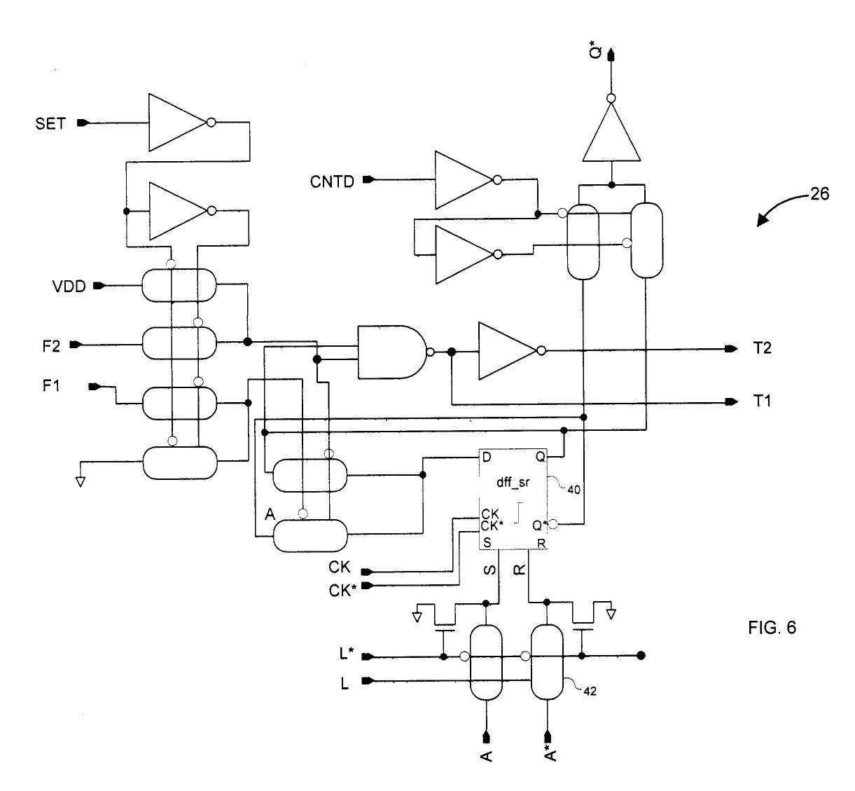

FIG. 6 is a schematic diagram for a test counter section 26, according to an embodiment of the present invention. It should be understood that the implementation depicted in FIG. 6 is merely exemplary and that other implementations are contemplated, would be understood by those of ordinary skill, and are within the scope of present invention. Test counter section 26 cooperates with other test counter sections 26 to count in set increments or decrements from some initial value that may be loaded into the test counter sections 26.

As shown, test counter section 26 has an input node SET to receive a bit signal (SETR[i], SETC[i]), input nodes A, A* to receive bit signals (AR[i], AR*[i]; AC[i], AC*[i]) for an initial address (row or column), an input node CNTD to receive a countdown (CRNTD, CCNTD) signal, input nodes F1, F2 to receive signals from a another test counter section 26 to which it is connected, input nodes CK, CK* to receive clock (LCK, LCK*) signals, and input nodes L, L* to receive the load row address (or load column address) signals.

Test counter section 26 may include a flip-flop 40, which may form part of a shift register. In one embodiment, this flip-flop 40 can be a positive-edge-triggered D set-reset flip-flop (dff_sr). The address bit signals (AR[i], AR*[i]; AC[i], AC*[i]) may be applied to the set (S) and reset (R) inputs of flip-flop 40 through pass gates 42 (only one of which is labeled for clarity), depending on the values of the load address (LRA or LCA) signals. This allows a respective bit of an initial address to be set in the test counter section 26. Either of the output Q, Q* signals of the flip-flop 40 may be used for the respective output address bit signal (TRA[i] or TCA[i]) of the test counter section 26, depending on whether the test address counter is counting up or counting down. The value of the input signal (CRNTD or CCNTD) at the CNTD node will be low (“logic 0”) if the test address counter is counting up, and the value of the signal at the CNTD node will be high (“logic 1”) if the test address counter is counting down.

The output Q, Q* signals of the flip-flop 40 may also be fed back as input at the D input, depending on the values of the signals at F1, F2 and SET nodes of the test counter section 26. If it is desired that the bit value for test counter section 26 be the least significant bit for counting, then the value of the signal (SETR[i] or SETC[i]) at the SET input node will be high, and the Q* signals will be fed back to the D input. Otherwise, depending on the voltage values of F1 and F2 signals, either Q or Q* signals will be fed back to the D input. Note that the F1 and F2 signals may always be complements of each other. The test counter section 26 performs logic on the F2 signal to generate the T1, T2 signals, which may be output to another test counter section 26.

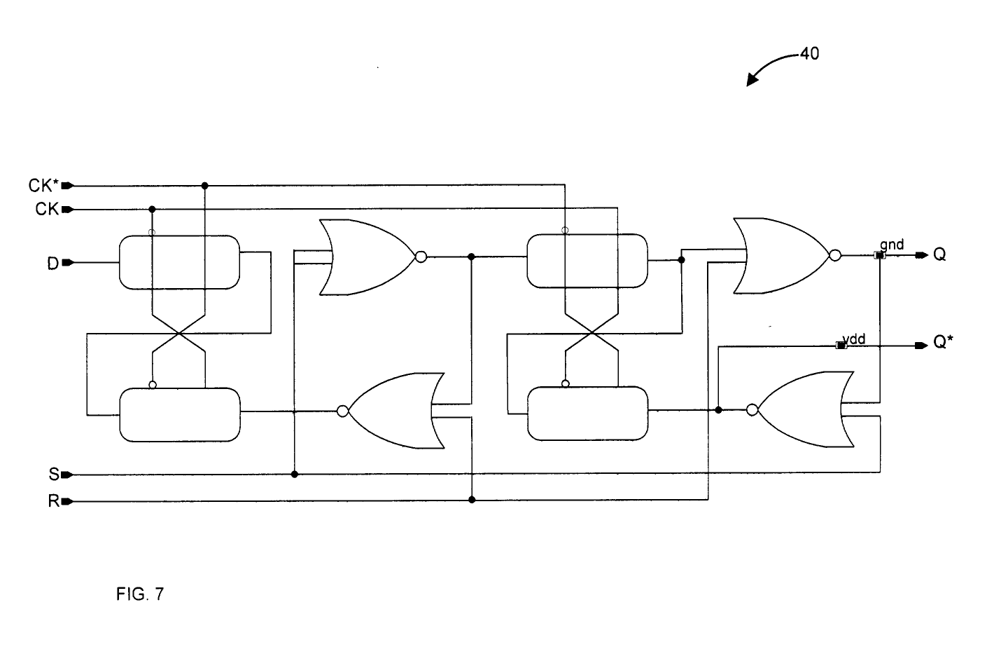

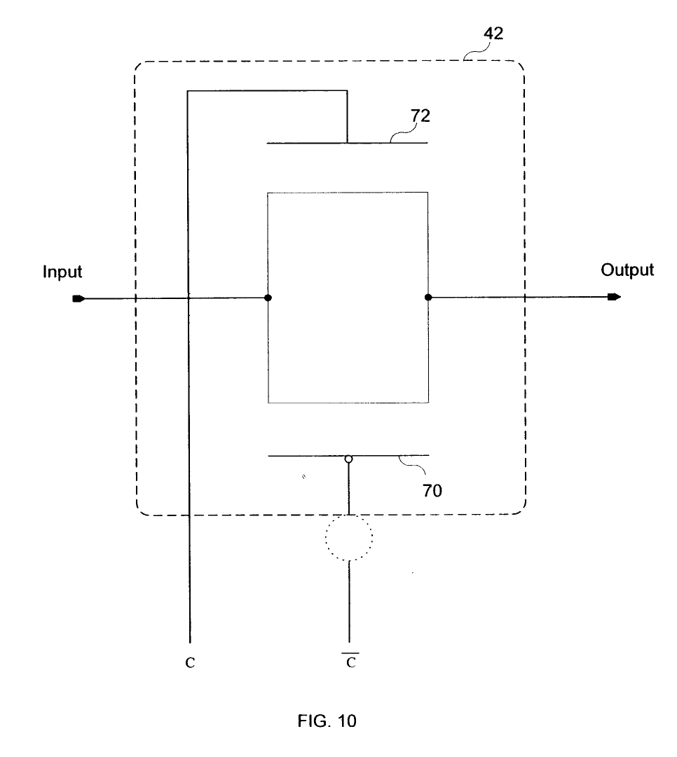

A schematic diagram of an exemplary implementation for flip flop 40, according to an embodiment of the present invention, is shown in FIG. 7. A schematic diagram of an exemplary implementation for pass gate 42 is shown in FIG. 10.

Initial Address Latch

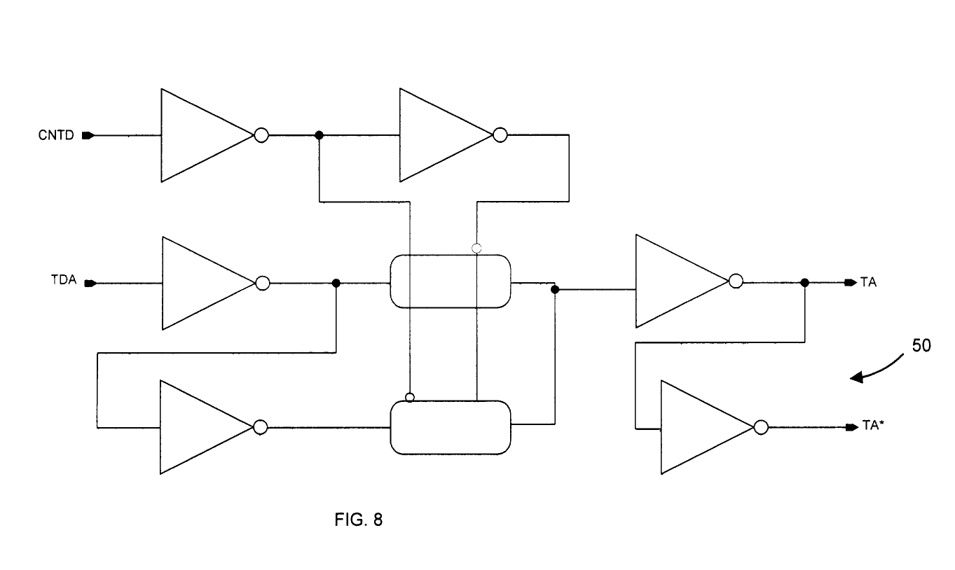

FIG. 8 is a schematic diagram of an initial address latch 50, according to an embodiment of the present invention. It should be understood that the implementation depicted in FIG. 8 is merely exemplary and that other implementations are contemplated, would be understood by those of ordinary skill, and are within the scope of present invention.

A plurality of such initial address latches 50 may be used for implementing row initial address latching component 22 and column initial address latching component 32 (shown in FIGS. 2 and 3, respectively). In one embodiment, eight such initial address latches may be used for each of row initial address latching component 22 and column initial address latching component 32.

Initial address latch 50 receives the appropriate count down signal (CRNTD or CCNTD) at a CNTD node, and a respective test data (TD[i]) bit signal at a TDA node. Initial address latch 50 generally functions to latch the value of the respective test data bit signal for input into a test address counter as part of an initial address.

LSB Latch

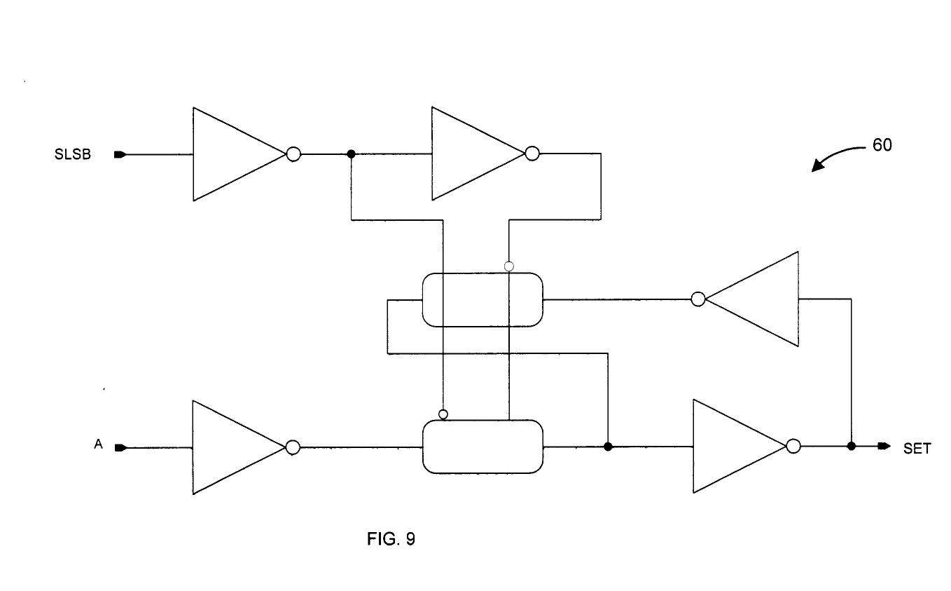

FIG. 9 is a schematic diagram of an LSB latch 60, according to an embodiment of the present invention. It should be understood that the implementation depicted in FIG. 9 is merely exemplary and that other implementations are contemplated, would be understood by those of ordinary skill, and are within the scope of present invention.

A plurality of such LSB latches 60 may be used for implementing row LSB latching component 20 and column LSB latching component 30 (shown in FIGS. 2 and 3, respectively). In one embodiment, twelve such LSB latches may be used for row LSB latching component 20, and eight such LSB latches may be used for column LSB latching component 30.

LSB latch 60 receives the appropriate set LSB signal (SRLSB or SCLSB) at a SLSB node, and a respective test data (TD[i]) bit signal at node A. LSB latch 60 generally functions to latch the value of the respective test data bit signal for input into a test address counter for defining a LSB.

FIG. 10 illustrates an exemplary implementation for a pass gate 42 which is shown, for example, in FIGS. 6 through 9. As shown, pass gate 42 comprises a P-type transistor 70 and an N-type transistor 72 with their sources and drains coupled together. An enable signal C is applied to the gate of transistor 72, and the inverse of the enable signal C is applied to the gate of transistor 70. An input terminal of pass gate 42 receives an input signal, and an output signal appears at an output terminal for pass gate 42. In operation, when the value of the enable C is low (and, consequently, the value of the inverse of the enable signal is high), the value of the input signal is passed through pass gate 42 as the value of the output signal.

Although the present invention and its advantages have been described in detail, it should be understood that various changes, substitutions, and alterations can be made therein without departing from the spirit and scope of the invention as defined by the appended claims. That is, the discussion included in this application is intended to serve as a basic description. It should be understood that the specific discussion may not explicitly describe all embodiments possible; many alternatives are implicit. It also may not fully explain the generic nature of the invention and may not explicitly show how each feature or element can actually be representative of a broader function or of a great variety of alternative or equivalent elements. Again, these are implicitly included in this disclosure. Where the invention is described in device-oriented terminology, each element of the device implicitly performs a function. Neither the description nor the terminology is intended to limit the scope of the claims.

What is claimed is:

1. A system for internally generating addresses for testing in an integrated circuit device having an array of addressable locations, said addresses being defined by N address bits, the system comprising:
a first latching component for receiving and latching a value for an initial address;
a second latching component for receiving and latching data for designating one of the N address bits as a least significant bit for counting; and
a test address counter coupled to the first latching component and the second latching component, the test address counter operable to generate a sequence of addresses for accessing a plurality of addressable locations in the array, wherein the sequence of addresses is represented by respective values which are derived by incrementing or decrementing the one of the N address bits designated as the least significant bit from the value for the initial address, wherein the first address of the sequence is the initial address;
wherein the first latching component, the second latching component, and the test address counter are implemented on the integrated circuit device.

2. The system of claim 1 wherein the initial address comprises a plurality of bits and the test address counter comprises a plurality of test counter sections, each test counter section operable to receive one of the bits of the initial address.

3. The system of claim 1 wherein the test address counter comprises a plurality of test counter sections coupled in cascode arrangement.

4. The system of claim 3 wherein the test address counter comprises N test counter sections, each of the N test counter sections associated with a respective one of the N address bits and operable to generate a separate value for the respective one of the N address bits for each address in the sequence.

5. The system of claim 1 wherein the array of addressable locations is a memory array.

6. The system of claim 1 wherein the array of addressable locations is a logic array.

7. A system for testing an array of addressable locations implemented on an integrated circuit device, each location identified by a respective address represented by a respective N-bit number, the system operable to receive data for setting an initial address and for designating a least significant bit for the N-bit numbers, the system operable to generate a sequence of addresses beginning with the initial address and derived by incrementing or decrementing the least significant bit.

8. The system of claim 7 wherein the array of addressable locations is a memory array.

9. The system of claim 7 wherein the array of addressable locations is a logic array.

10. A system for internally generating addresses for testing in an integrated circuit device having an array of addressable locations, said addresses being defined by N address bits, the system comprising:
means for receiving and latching a value for an initial address;
means for receiving and latching data for designating one of the N address bits as a least significant bit for counting; and
means for generating a sequence of addresses for accessing a plurality of addressable locations in the array, the means for generating coupled to the means for latching, wherein the sequence of addresses is represented by respective values which are derived by incrementing or decrementing the one of the N address bits designated as the least significant bit from the value for the initial address, wherein the first address of the sequence is the initial address.
